(19) United States
(12) Patent Application Publication
(10) Pub. No.: US 2010/0019940 A1
(43) Pub. Date: Jan. 28, 2010

(54) CHARACTER INPUT DEVICE

(76) Inventor: Eui Jin Oh, Daejeon (KR)

Correspondence Address: LEXYOUME IP GROUP, LLC, 5180 PARKSTONE DRIVE, SUITE 175, CHANTILLY, VA, 20151, US

(21) Appl. No.: 12/526,522

(22) PCT Filed: Feb. 13, 2008
(86) PCT No.: PCT/KR2008/000862

§ 371 Date: Aug. 10, 2009

(30) Foreign Application Priority Data
Feb. 13, 2007 (KR) 10-2007-0014903
Feb. 16, 2007 (KR) 10-2007-0016512

(51) Int. Cl. H03K 17/94

(52) U.S. Cl. 341/20

(57) ABSTRACT

Disclosed herein is a character input device including a plurality of directional input keys. The character input device includes input means including four input keys that are arranged in four radial directions around a center so that distances between adjacent input keys are uniform. The respective input keys are provided such that they can be moved toward a plurality of direction indication locations arranged in radial directions around a reference location, and can perform directional movement input. Accordingly, each of characters, numbers, and symbols can be input through a single action using four input keys, thereby enabling the minimization of the space and rapid and accurate character input. Furthermore, characters arranged on respective input keys are separately arranged in the directions of the movement of input keys, and thus a user can easily become accustomed to the operation of the input keys, thereby enabling efficient character input.

### TECHNICAL FIELD

The present invention relates, in general, to a character input device, and, more particularly, to a character input device that is capable of inputting each of characters, numbers and symbols through a single action using a minimal number of input keys, thereby improving the efficiency of the input of characters.

### BACKGROUND ART

With the development of software and semiconductor technology and data processing technology, information devices are gradually becoming small, and the amount and importance of characters input using such information devices is gradually increasing.

Meanwhile, the input of various characters or instructions to such information devices exhibits many problems. For example, input devices, such as keyboards, used in Personal Computers (PCs) or notebook computers cause difficulty in realizing small-sized information devices because there is a limitation on the reduction in the size thereof, and touch screen schemes used in Personal Data Assistants (PDAs) and keypad schemes used in mobile phones are inconvenient because the speed of input is slow and the incidence of erroneous input is high.

In order to input letters, numbers and symbols to the above-described information devices, such as PCs, notebook computers, PDAs or mobile phones, at a higher speed, it is necessary to perform a so-called one stroke-one phoneme input, in which one phoneme character is input through one input action at a higher speed. When such one stroke-one phoneme input is applied to the Korean alphabet, it is necessary to provide buttons or input keys for inputting 24 or more characters on an information device. When the target language of input is English, Japanese or some other language, a larger number of buttons or input keys is required than in the case of the Korean alphabet.

However, since conventional input devices used in various types of information devices adopt a scheme of assigning characters to respective input keys and inputting the characters by striking or pressing the input keys using fingers, it is difficult to arrange 24 or more finger-sized input keys on a personal mobile information terminal having a small area for the arrangement of input keys, such as a mobile phone.

Accordingly, if each input key enables directional input, a large amount of data can be processed using a smaller space. In connection with this, a patent for a sliding key device for a terminal, in which keys 2 capable of sliding in multiple directions in a terminal 1 are provided, was applied for in Korean Patent Application No. 10-2004-79085. However, although respective input keys of the keypad of the mobile phone are described as enabling directional input in the sliding key device, the sliding key device has a large number of directional input keys and the input keys are densely aggregated in vertical and lateral directions, so that the accuracy of input is low and the use of the device is very inconvenient. For example, when input key No. 1 is moved to the north and input key No. 8 is moved to the south or input key No. 9 is moved to the west, a user must perform input while viewing a keypad, and in addition, it is difficult to perform accurate input when input is performed.

Furthermore, the fact that it is difficult to arrange 24 or more input keys having the size of a finger on a personal portable information terminal is the reason why it has been difficult to realize a small-sized keyboard. In the case of mobile phones, since 24 or more Korean alphabet letters are input using only 12 buttons, it is inevitable to arrange a plurality of letters on each button, with the result that a repeated input phenomenon, in which an input action is repeated twice or three times to input one letter (phoneme), occurs frequently. Accordingly, input is slow and inconvenient.

Although a character input method of inputting characters through combination, known as Cheonjiin, has been proposed in order to overcome the above problem, the repeated input phenomenon is not solved using this method.

Furthermore, technologies, including a roll-up keyboard, which can be rolled up and then carried, and a virtual laser keyboard, which is configured to project an image of a keyboard onto a surface, detect the locations of fingers when actions similar to keyboard input actions are perform on the image using the fingers and receive input, have be proposed.

However, such types of input devices have problems in that they are inconvenient in that they must always be carried, and in that the types of input device are not suitable for application to personal portable information terminals requiring input in the state in which the personal portable information terminals are held in the hands while moving because input can be performed only in the state in which those types of input devices are placed on support surfaces.

### DISCLOSURE OF INVENTION

### Technical Problem

Accordingly, an object of the present invention is to provide a character input device that is capable of inputting each of characters, numbers and symbols through a single action using a minimal number of input keys, thereby reducing the space required for character input and enabling fast and accurate character input.

Another object of the present invention is to provide a character input device that is capable of discriminating between inward and outward signals input through input means, thereby enabling the accurate input of data using even a small area.

A further object of the present invention is to provide a character input device that is capable of rapidly inputting data because repeated input is not required and touch input can be performed, and that is capable of accurately inputting data because the range of movement for input is narrow, thus preventing erroneous input attributable to a user's carelessness.

Yet another object of the present invention is to provide a character input device that is capable of inputting a large amount of data using even a small area, and that is capable of being applied to various information devices, thereby realizing lightweight and small information devices.

Still another object of the present invention is to provide a character input device in which a plurality of input keys capable of performing directional input is arranged in four directions, namely, south, north, west and east, in a radial arrangement and in which various characters can be input using the respective input keys.

### Technical Solution

In order to accomplish the above objects, the present invention provides a character input device including a plurality of directional input keys, including input means including four input keys that are arranged in four radial directions around a center so that distances between adjacent input keys are uniform; wherein the respective input keys are provided such that they can be moved toward a plurality of direction indication locations arranged in radial directions around a reference location, and can perform directional movement input for inputting characters assigned to the respective direction indication locations.

The input means may be implemented using input keys. Although the input keys may be provided in the form of stick-type input keys or sliding button-type input keys, the input keys are not limited thereto. Meanwhile, the input means will be described as an input unit in the following embodiments.

The directional movement input may be provided to enable two or more-stage input, that is, multi-stage input, based on the moving distance of each of the input keys.

Each of the input keys may be provided to enable directional pressing input in which the entire input key is moved in a vertical direction.

The directional pressing input may be provided to enable two or more-stage input, that is, multi-stage input, based on any one of differences in pressing distance and pressing pressure of the input key.

Consonant characters are input through the directional movement input and vowel characters are input through the directional pressing input.

The character input device may further include a central input key that is provided at the center and enables one or more of the directional movement input and the directional pressing input.

The central input key may be provided to enable two or more-stage input, that is, multi-stage input, and consonant characters may be input through the directional movement input of the four input keys and vowel characters may be input through the directional movement input of the central input key.

The input keys may be five or more in number.

The input keys may be arranged at regular intervals in a circle having a predetermined radius around the center, vowel characters may be input through directional movement input of the respective input keys in radial directions of the circle, and consonant characters may be input through direction movement input in directions perpendicular to the radial directions.

The input keys may be arranged at regular intervals in a circle having a predetermined radius around the center, consonant characters may be input through directional movement input of the respective input keys in radial directions of the circle, and vowel characters may be input through direction movement input in directions perpendicular to the radial directions.

Consonant characters may be input through forward/backward directional movement input of the respective input keys in radial directions of the circle, and vowel characters may be input through forward/backward direction movement input in directions perpendicular to the radial directions.

Vowel characters may be input through forward/backward directional movement input of the respective input keys in radial directions of the circle, and consonant characters may be input through forward/backward direction movement input in directions perpendicular to the radial directions.

The input keys may be stick-type input keys that can be titled from the reference location toward the respective direction indication locations.

The input keys may be sliding button-type input keys that can be laterally moved from the reference location toward the respective direction indication locations.

The character input device may further include return units for returning the input keys to the reference location after performing the directional movement input.

The character input device, including the plurality of input key or the central input key, includes two sets of character input devices on right and left sides.

Consonant characters may be input through any one of the directional movement input, the directional pressing input and the central input.

The directional movement input may be provided to enable two-stage input in the radial directions and one-stage input in directions perpendicular to the radial directions, the directional pressing input may be provided to enable two-stage input, consonant characters can be input through the directional movement input, and vowel characters can be input through the directional pressing input.

The directional movement input may be provided to enable one-stage input in directions perpendicular to the radial directions, the directional pressing input may be provided to enable two-stage input, the central input is provided to enable two-stage input in the radial directions, vowel characters may be input through the directional pressing input, and consonant characters may be input through the directional movement input and the central input.

Furthermore, the directional movement input may enable two or more-stage input, that is, multi-stage input, in each of a state in which each of the input keys is pressed and a state in which the input key is not pressed based on a distance of the input key.

In this case, each of the input keys may be provided to enable directional pressing input in which the entire input key is moved in a vertical direction.

Furthermore, the directional pressing input may be provided to enable two or more-stage input, that is, multi-stage input, based on any one of differences in pressing distance and pressing pressure of the input key.

The character input device may further include a central input key that is provided at the center and enables one or more of the directional movement input and the directional pressing input in which the entire input key is moved in a vertical direction.

Furthermore, in order to accomplish the above objects, the present invention provides a character input device including input means configured to have a plurality of directional input keys and to input data in response to one or more signals, a detection unit for detecting one or more signals from the input means, and a control unit for detecting one or more effective signals from among the signals detected by the detection unit and creating data, wherein the input means is configured to include a first input unit, which is a reference, and second input units, which are formed in radial directions from the first input unit and on which characters arranged in a plurality of columns are arranged; and the first input unit or each of the second input units enables directional movement input and pressing input (vertical pressing input), and inputs specific data corresponding to a character arranged at a relevant location through the directional movement input or the pressing input.

Here, the input means, the first input unit, and the second input units will be described as being an input unit, a central input unit, and input keys arranged around the central input key in embodiments, which will be described below.

Furthermore, the directional movement input of the first input unit or the second input units is performed via two distinct signals, the directional movement input of the second input unit is divided into a signal related to a short distance and a signal related to a short distance, and the pressing input of the first input unit or each of the second input units is performed via two distinct signals, and

Furthermore, the directional movement input of the second input units may be divided into inward input in a direction toward the first input unit and outward input in a direction away from the first input unit, specific data corresponding to characters arranged at relevant locations may be input based on the inward input and the outward input, the data input through the directional movement input of the second input units may be consonants, and data input through the directional movement input of the first input unit is vowels.

Furthermore, the second input units are configured to input data, such as characters, numbers or symbols, or perform functions (inputs), such as Mode Switch, Cancel, Enter or Space, via the four radial signals, except for the inward and outward signals.

Furthermore, data, such as a character, a number or a symbol, is input or a function (input), such as Mode Switch, Cancel, Enter or Space, is input through the pressing input of the first or each of the second input units.

The first input unit and the second input units are input key-type input units that are formed as separate input keys. Here, the input keys are respective device pointers, and the second input units are provided with protrusions in order to easily discriminate between distances related to input of signals.

Furthermore, the input means is implemented on any one of a touch screen. In the case in which the input means is implemented on the touch screen, the first input unit of the input means is implemented on a screen in a form of a spot for indicating a reference, and the second input units of the input means are formed in a predetermined region in a circumferential direction around the first input unit. The input means can be moved across the screen, and the movement of the input means is performed after the first input unit or one of the second input units is clicked twice within a predetermined time. Furthermore, the input device is configured such that a waiting region, to which the first input unit can be moved, is provided on one side of the screen, the region of the second input units disappears when the first input unit is moved to the waiting region, and the region of the second input units appears when the first input unit is moved from the waiting region. The second input units are configured such that transparency thereof can be adjusted. It is apparent that the input means may be implemented a touch pad or a touch keypad, as well as the touch screen.

Meanwhile, the present invention provides a character input device including input means configured to have a plurality of directional input keys and to input data in response to one or more signals, a detection unit for detecting one or more signals from the input means, and a control unit for detecting one or more effective signals from among the signals detected by the detection unit, and creating data, wherein the input means is configured in a form of a disk in which a first input unit, which is a reference, and second input units, which are formed in radial directions around the first input unit and on which characters arranged in a plurality of columns are arranged, are integrated together; and the first input unit or each of the second input unit enables directional movement input and pressing input (vertical pressing input), and inputs specific data corresponding to a character arranged at a relevant location through the directional movement input or the pressing input.

Furthermore, the disk can be laterally moved in a circumferential direction, the directional movement input of the first input unit or the second input units is performed via two distinct signals, and the pressing input of the first input unit or the second input units is performed via two distinct signals.

Furthermore, the directional movement input of the second input units is divided into inward input in a direction toward the first input unit and outward input in a direction away from the first input unit, and specific data corresponding to characters arranged at relevant locations is input based on the inward input and the outward input, the detection unit determines that a signal in question is an outward signal if only a signal from one of the second input units is detected, and determines that a signal in question is an inward signal if a signal from the first input unit is detected within a predetermined time after a signal from one of the second input units is detected.

Furthermore, data input through the directional movement input of the first input unit is a vowel, and data input through the directional movement input of each of the second input units is a consonant.

Furthermore, the second input units are configured to perform a volume adjustment function or a mouse scrolling function via a continuous signal in a circumferential direction, and the input means further includes third input units in a circumferential direction around the second input units.

Prior to a detailed description of the present invention, it should be noted that all technical terms and scientific related terms that are not specially defined in the present specification have general meanings that are widely used in the technical field to which the present invention pertains. However, the following terms are defined in order to clarify the range of the present invention, as follows:

Definitions of Terms

1) In the present specification and claims, the term “directional movement input M (see FIG. 1)” refers to the input of a character, a number or a symbol, desired by a user, through the movement of an input key 10 that is performed in such a way as to laterally move the entire input key 10′ (see FIG. 3), provided in the input unit 1 of a character input device according to the present invention, in a certain direction in the same plane (lateral or sliding movement) (see FIGS. 3 to 5) or tilt a stick-type input key 10, such as a joystick, at a certain angle or in a certain direction (see FIGS. 1 and 2).

However, the type of action of the input unit 10 is not limited to the above-described types. The input unit 10 is made of elastic (flexible) material, and may be provided with detection means capable of detecting slight movement of the input unit 10.

In the above-described case, when force is applied to the input unit 10 in a lateral or vertical direction, the effect in which the input unit 10 has been moved and input has been performed can be transferred to a control unit (40), even though the location of the entire input unit 10 is not changed.

Accordingly, the “second directional input M” in the present specification is not limited to the action and type of the input unit 10. The second directional input includes all the actions of providing a result in which the input unit 10 has been moved and input has been performed to the control unit of the character input device, including the action of pushing the input unit 10 in a lateral direction or a direction similar to the lateral direction (or applying force).

2) In the present specification, the term “directional pressing input(P)” refers to the input of a character, a number or a symbol, desired by a user, through an action of raising or lowering the entire input key 10 in a vertical direction.

3) In the present specification, the term “vowel” refers to a character, the sound of which corresponds to a vowel of the Korean alphabet in the case of a foreign language, or a character that belongs to an alphabet group having a smaller number of characters when the alphabet of a foreign language is divided into two groups according to linguistic classification criteria.

4) Meanwhile, in the present specification, the term “character” refers not only to a character in a narrow sense, that is, a language-based character, such as a Korean alphabet character, an English character or a Japanese character, but also to numbers, symbols and the like.

### Advantageous Effects

Accordingly, according to the character input device of the present invention, each of characters, numbers, and symbols can be input through a single action using four input keys (or four input keys as well as a central input key), thereby enabling the minimization of the space required for input of characters, and rapid and accurate character input.

Furthermore, characters arranged on respective input keys are separately arranged in the directions of the movement of input keys, and thus a user can easily become accustomed to the operation of the input keys, thereby enabling efficient character input.

Furthermore, according to the present invention, there are advantages in that a large amount of data can be input within a small area because the simultaneous operation of a first input unit and a second input unit is employed, and in that erroneous operation attributable to a users' carelessness can be prevented because repeated actions are not required, thereby enabling accurate data input.

Furthermore, according to the present invention, there are advantages in that the convenience of input of data can be increased through a simple construction and method of use, and in that lightweight and small information devices can be realized because the present invention can be applied to information devices.

### BRIEF DESCRIPTION OF THE DRAWINGS

FIG. 1 is a perspective view showing a character input device according to a first embodiment of the present invention;

FIG. 2 is a sectional view of an input key shown in FIG. 1;

FIG. 3 is a perspective view showing a variant of the first embodiment according to the present invention;

FIG. 4 is a perspective view of a character input device according to a second embodiment of the present invention;

FIGS. 5 and 6 are sectional views showing various embodiments of the input key shown in FIG. 4;

FIG. 7 is a perspective view showing a variant of the second embodiment according to the present invention;

FIG. 8 is a conceptual diagram illustrating a method of inputting consonant and vowel characters based on the directional movement input and directional pressing input of each input key in the character input device according to the present invention;

FIG. 9 is a conceptual diagram illustrating a method of inputting characters in the case in which a central input key is included in the character input device of FIG. 8;

FIG. 10 is a perspective view illustrating the combinational input of input keys in the character input device according to the present invention;

FIGS. 11 and 12 are perspective views illustrating a method of inputting Korean characters;

FIGS. 13 and 14 are perspective views illustrating a method of inputting Japanese characters;

FIG. 15 is a plan view showing a character input device according to a third embodiment of the present invention;

FIG. 16 is a configuration diagram illustrating an implementation method through the embodiment shown in FIG. 15;

FIGS. 17 to 20 are diagrams showing the constructions of a character input device according to a fourth embodiment of the present invention;

FIG. 21 is a front view showing an example of the application of the embodiments shown in FIGS. 17 to 20;

FIG. 22 is a perspective view showing a character input device according to a fifth embodiment of the present invention;

FIG. 23 is a schematic sectional view showing the construction of the embodiment shown in FIG. 22;

FIG. 24 is a conceptual diagram illustrating the operation of the embodiment shown in FIG. 22;

FIG. 25 is a conceptual diagram showing an example of the arrangement of Korean characters in the embodiment shown in FIG. 22;

FIG. 26 is a conceptual diagram illustrating an example of input in the embodiment shown in FIG. 22; and

FIG. 27 is a perspective view showing a prior art device.

### MODE FOR THE INVENTION

A first embodiment of a character input device according to the present invention will be described in detail with reference to the accompanying drawings.

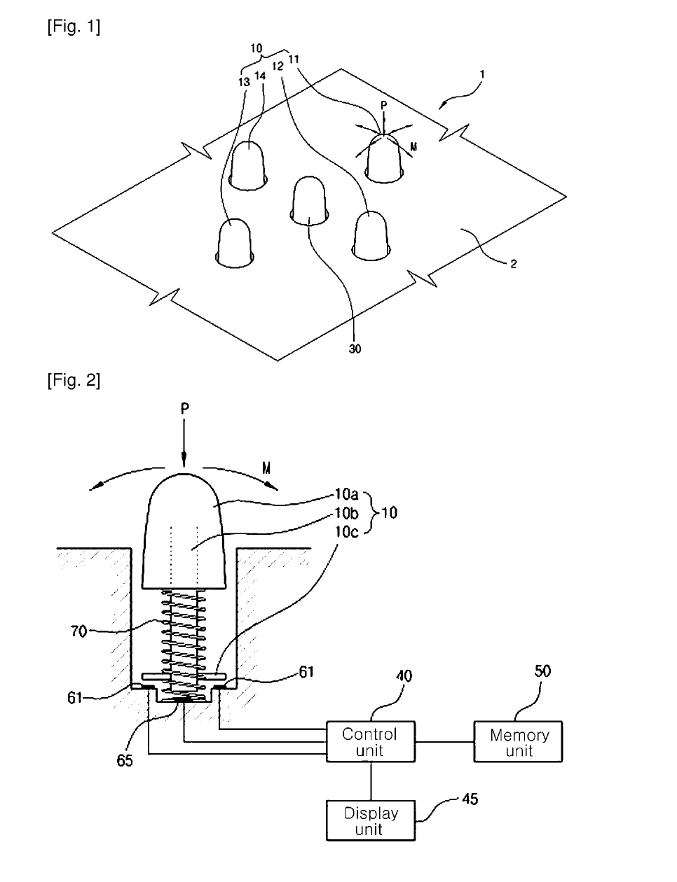

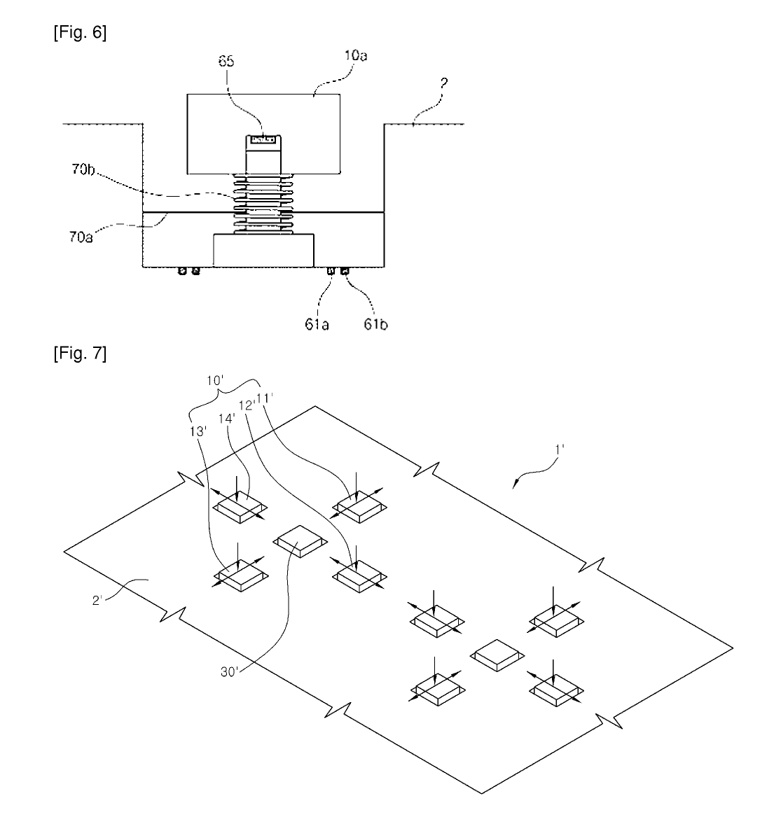

Referring to FIG. 1, in the character input device according to the present invention, an input unit 1 includes four input keys 10 that are respectively arranged in four radial directions from the center of the device so that distances between adjacent input keys 10 are uniform. The respective input keys 10 are provided to be movable to a plurality of direction indication locations M1, M2, M3 and M4 (see FIG. 6) arranged radially around a reference location, and are provided to be able to perform directional movement input M for inputting characters assigned to the respective direction indication locations M1, M2, M3 and M4.

Here, movement detection units 61 (see FIG. 2), for detecting the directional movement input M, and a control unit 40 for, in response to the results of the detection by the movement detection units 61, extracting characters, assigned to the direction indication locations M1, M2, M3 and M4, corresponding to locations at which the input keys 10 are detected, from a memory unit 45 and inputting them, may be further included.

Furthermore, a display unit 50 for displaying characters extracted by the control unit 40 may be further included.

FIG. 1 is a perspective view showing the input unit 1 of a character input device according to the present embodiment.

Referring to this drawing, a central input key 30 is provided at the center of a casing 2, and the four input keys 10 are arranged in a circle having a specific radius around the central input key 30 so that distances between adjacent input keys are uniform.

The input keys 10 may be arranged in various configurations. For example, as shown in the drawing, a first input key 11, a second input key 12, a third input key 13 and a fourth input key 14 may be sequentially arranged in the 12 o'clock direction, the 3 o'clock direction, the 6 o'clock direction and the 9 o'clock direction around the central input key 30.

As long as the input keys 10 are provided to enable the above-described directional movement input M and directional pressing input P, the input keys 10 may be any type of input keys among various types of input keys.

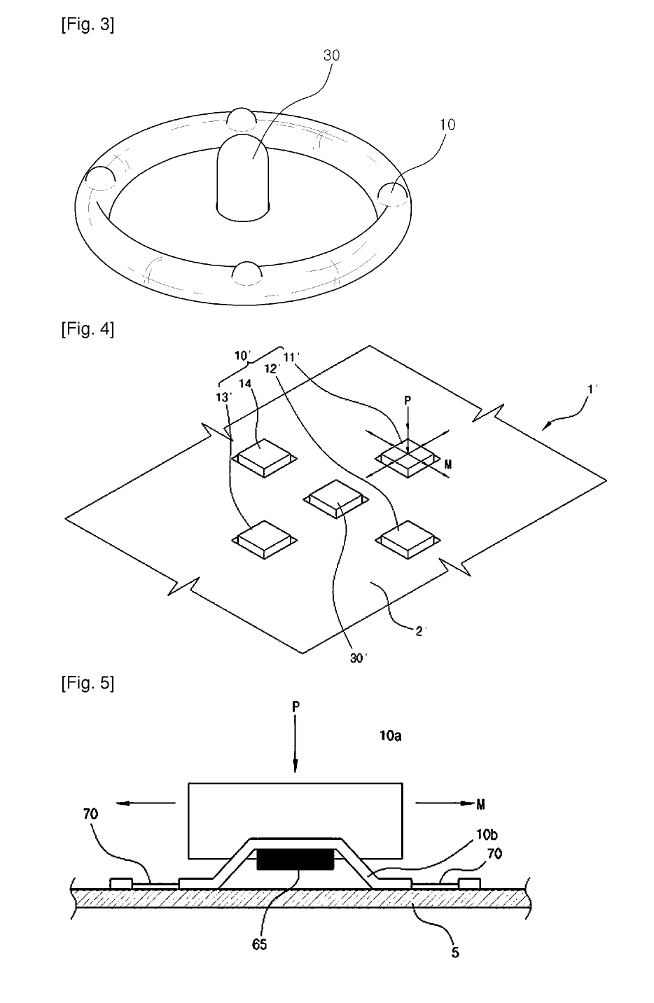

For example, stick-type input keys may be provided, as shown in FIG. 1, and sliding button-type input keys may be provided, as shown in FIG. 3.

Referring to FIG. 2, each of the input keys 10 according to the present embodiment may include a cap 10a, a support rod 10b inserted into the cap 10a and configured to extend toward the casing 2, and actuators 10c supported around the support rod 10b and configured to come into contact with the movement detection units 61 when the input key 10 is tilted.

The input key 10 is provided to be supported on the casing 2 by a return member 70, such as a coil spring and to be able to be tilted in various radial directions.

The actuators 10c are provided at respective radial locations corresponding to respective direction indication locations M1, M2, M3 and M4, and the actuators 10c are also provided at the respective radial locations, and thus the direction in which the input key 10 is tilted can be detected based on the location at which an actuator 10c and a movement detection unit 61 come into contact with each other.

Accordingly, the control unit 40 extracts character codes, assigned to the direction indication location M1, M2, M3 and M4, corresponding to locations at which contact is detected, from the memory unit 45, and inputs the characters.

A pressing detection unit 65 for detecting the vertical movement of the cap 10a is provided below the support rod 10b. The pressing detection unit 65 detects the support rod 10b when the support rod 10b is lowered and then comes into contact with the pressing detection unit 65 at the time of performing directional pressing input P, and transmits the results of the detection to the control unit 40.

The above-described movement detection units 61 and the above-described pressing detection unit 65 may be various types of detection units, such as contact sensors or pressure sensors.

Here, the directional movement input M and the directional pressing input P may be conducted in two or more stages. For a stick-type input key, optical sensors for detecting the extent of the tilting of the actuators 10c may be provided as the movement detection units 61, and a pressure sensor for detecting pressing distance or pressing pressure may be provided as the pressing detection unit 65.

The return member 70 is provided to return the input key 10 to the reference location after directional movement input M has been performed.

The return member 70 may be any one of various types of return members. For example, as shown in FIG. 2, a coil spring may be provided as the return member 70. Accordingly, the stick-type input key 10 is returned to the original location thereof by the restoring force of the return member 70 after the directional movement input M has been performed.

Furthermore, the input keys in the present embodiment may be combined into an integrated input key, as shown in FIG. 3.

Meanwhile, input keys 10′ may be sliding button-type input keys, as shown in FIGS. 4 to 6.

Referring to FIG. 5, a support 10b for spacing each of the sliding buttons 10a from the casing 2 by a predetermined distance is provided below the sliding button 10a. A pressing detection unit 65 for coming into contact with and contacting the casing 2 when directional pressing input P is performed is provided below the support 10b. In this case, it is preferred that the support 10b be made of material having predetermined elasticity.

For the sliding buttons 10a, one of various methods of detecting directional movement input M may be provided.

For example, as shown in FIG. 5, a touch pad 5 may be provided below the sliding button 10a to detect the contact location of the support 10b, which moves along with the sliding button 10a. As shown in FIG. 5, a movement detection unit 61, such as a contact sensor, may be provided on the path of the support 10b.

In this case, multi-stage directional movement input M may be implemented by sequentially arranging two or more movement detection units 61 along the path of the support 10b, as shown in FIG. 6.

Meanwhile, return members 70, which include elastic material, are provided between the support 10b and the casing 2, and return the input key 10′, which has performed directional movement input M, to the reference location, may be further included.

In the case of an input key 10 according to a second embodiment of the present invention shown in FIG. 6, a pressing detection unit 65 may be provided inside the sliding button 10a to perform directional pressing input P, and may be configured to come into contact with the support 10b when the sliding button 10a is raised.

Here, a central input key 30 has the same construction as the above-described input key 10 or 10′. Accordingly, for a description of the central input key 30, refer to the description of the input key 10.

FIG. 7 shows a variant of the character input device shown in FIG. 4. That is, although each input key 10 of FIG. 4 can perform directional movement input in four directions, that is, upward, downward, leftward and rightward directions, each input key 10 of FIG. 7 can perform directional movement input in inward and outward directions. Here, it is apparent that each input key of FIG. 7 can perform directional pressing input in the same way as each input key of FIG. 4.

Furthermore, since, in FIG. 7, each input key performs directional movement input in inward and outward directions and directional pressing input, input keys are provided in two sets in order to increase the number of input characters.

Meanwhile, although respective input keys are arranged around a central input key in four directions, the input keys may be arranged in 5 directions, 6 directions, 7 directions or 8 directions.

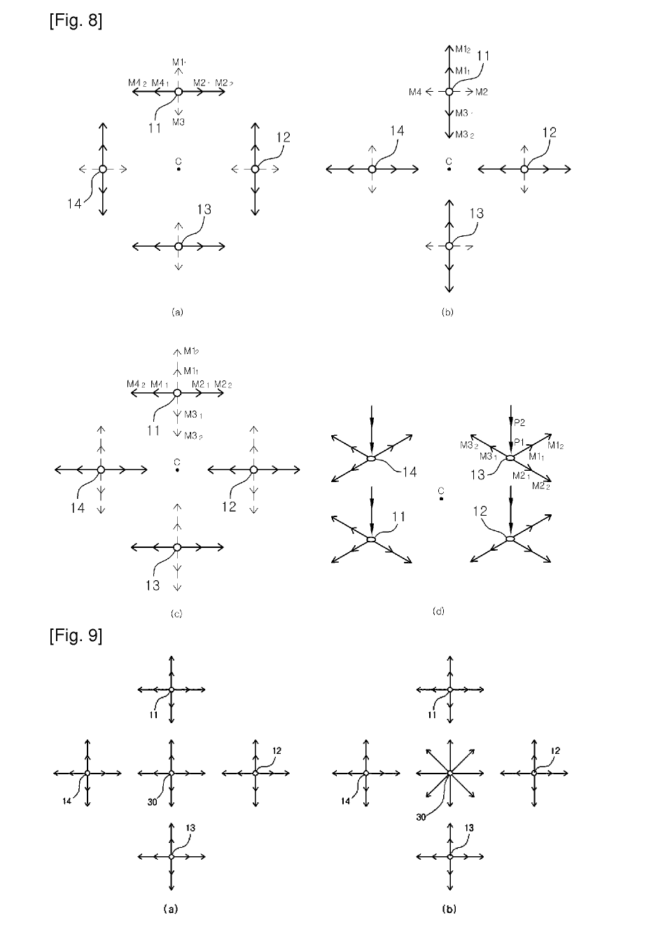

The operation of the character input device having the above-described structure according to the present invention will be described below with reference to FIGS. 8 and 9.

FIG. 8 shows a case in which a central input key 30 is not provided, and FIG. 9 shows a case in which a central input key 30 is provided.

Input keys 10 are provided to be four in number, as shown in FIG. 8, and each have a plurality of direction indication locations M1, M2, M3 and M4.

The number and directions of the direction indication locations M1, M2, M3 and M4, provided for each of the input keys 10, may be uniform, as shown in FIG. 8(c), or may vary, as shown in FIGS. 8(a), (b) and (d).

FIG. 8(a) shows a case in which, on the basis of a center C, each input key 10 is assigned one-stage directional movement input M in a radial direction and two-stage directional movement input M in a circumferential (tangential) direction.

In this case, since each input key 10 can be assigned six characters corresponding to M1, M2₁, M2₂, M3 and M4₁ and M4₂, a total of 24 characters (symbols, numbers, or the like) may be assigned.

Furthermore, the radial movement of each input key 10 (indicated by dotted lines in FIG. 8(a)) is assigned vowel characters, and the circumferential movement thereof (indicated by solid lines) may be assigned consonant characters.

In this case, since consonant characters and vowel characters are assigned to different input directions of each input key 10, a user can be easily accustomed to the operation of the input keys 10.

FIG. 8(b) shows the case in which directional movement input M in a radial direction is assigned consonant characters, and directional movement input M in a circumferential direction is assigned vowel characters, in a manner opposite that of FIG. 8(a).

Meanwhile, as shown in FIG. 8(c), each input key 10 may be configured to perform two-stage input in each of four radial directions.

In this case, the total number of characters that can be assigned to the input keys 10 is 8×4, that is, 32. Accordingly, locations remain after 24 Korean characters and 26 English characters 26 have been arranged, and symbols, numbers, and functions, such as Enter, Space and Cancel, are assigned to the remaining locations.

Furthermore, in the case of character input, vertical directional movement input M may be assigned vowel characters, and lateral directional movement input M may be assigned consonant characters.

FIG. 8(d) shows a case in which directional pressing input P is provided along with directional movement input M.

In the case in which both directional movement input M and directional pressing input P are employed, 8 characters are added to the above-described 32 characters, resulting in the assignment of a total of 40 characters.

Since 32 characters can be assigned if needed even when some directional movement input M is prohibited, as shown in FIG. 8(d), symbols, numbers and functions may be assigned, in addition to Korean characters and English characters.

FIG. 9 shows the case in which a central input key 30 is included.

FIG. 9(a) shows the case in which a central input key 30 is provided to perform two-stage directional movement input M in each of four radial directions, like outside input keys 10, and FIG. 9(b) shows the case in which a central input key is provided to perform only one-stage directional movement input M in each of eight radial directions.

Here, the number of direction indication locations M1, M2, M3 and M4 for each of the above-described input keys 10 and central input key 30 may be freely set to, for example, four directions or eight directions, and multi-stage input may be freely applied to the input keys.

Accordingly, the total number of characters that can be input through a single action using four input keys 10 may range from 16 to 50 depending on the number of radial directions, the number of multi-stage inputs, the application of directional pressing input P and the application of a central input key 30.

Furthermore, when, in the character input device according to the present invention, the input unit 1 is provided in two sets on the right and left sides, the number of characters that can be input increases twice, in which case consonant characters and vowel characters may be separately arranged in the two sets of input units 1, or symbols and numbers may be separately arranged in the two sets of input units 1.

Accordingly, in addition to 26 characters (Korean characters and English characters are assigned to the same input keys, and are separately input through mode switching) and 12 numbers (0˜9, *, #), both functions (Enter, Space, Cancel, etc.) and mode switching special characters can be arranged.

Meanwhile, it is possible to input a new character by performing the directional pressing input of each input key in the state in which directional movement input has been performed using the central input key. Furthermore, more numbers and symbols can be input both through the combinations of the directional movement input of the central input key and the directional movement input of the respective input keys and the combinations of the input of the central input key and the input of the input keys.

For this purpose, it is preferred that each of the central input key and the respective input keys fall within the range of a single finger (for example, the thumb) so that the input key can be pressed by a single finger. This is useful for the case in which, when the character input device is used as a mouse, the central input key is used to move a mouse pointer and each of the respective input keys is used as the left button, right button or scroll button of the mouse to execute one or more commands. In this case, dragging or file dragging can be performed by manipulating the left button or right button of the mouse while moving the mouse pointer, and thus the simultaneous manipulation of the central input key and an input key enables very efficient performance to be achieved.

Furthermore, touch detection means for detecting the touch of a finger on the central input key is further included, and a character that can be input through each input key may vary depending on whether the touch of a finger is detected by the touch detection means.

Accordingly, when each of the central input key and the respective input keys is normally pressed, a character is input. In the state in which a finger touches the central input key (a touch is detected by the touch detection means), the input unit can be immediately used without switching to a mouse mode.

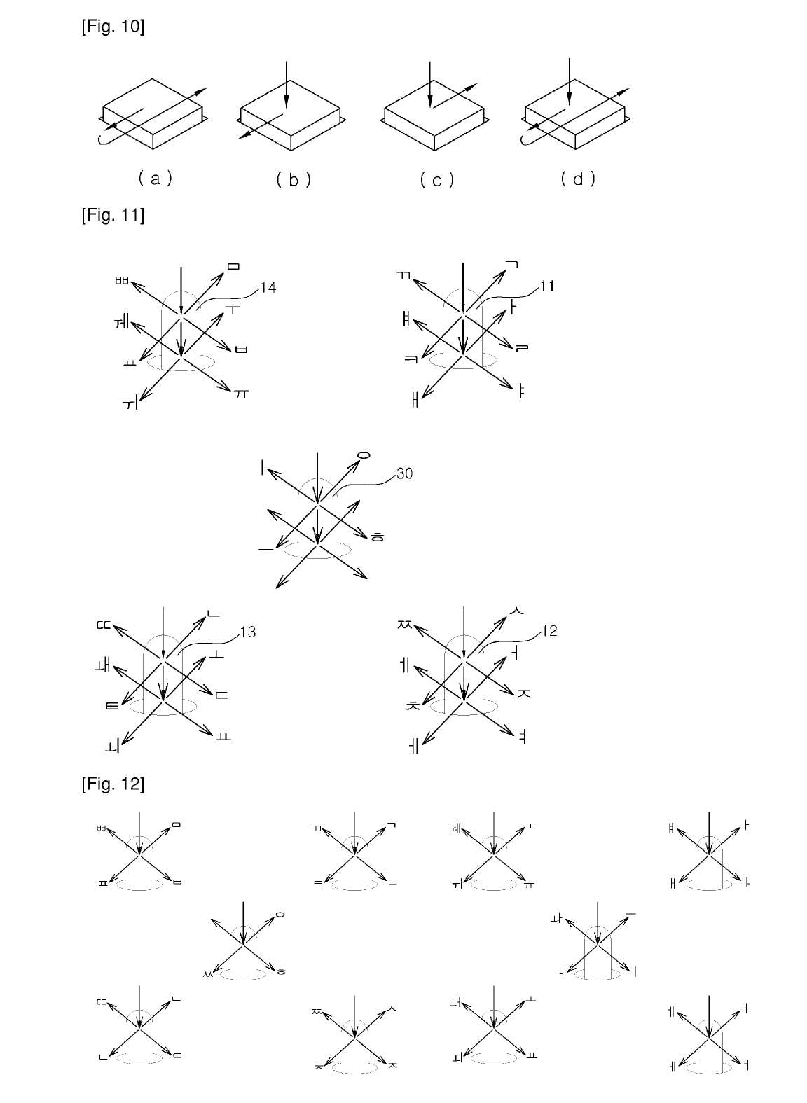

Meanwhile, FIG. 10 is a drawing illustrating the combinations of directional movement input and directional pressing input. The combinations can be usefully used in the embodiment shown in FIG. 7. In greater detail, in FIG. 10(a), a new character is input by successively performing inward input and outward input, in FIGS. 10(b) and 10(c), a new character is input by performing directional pressing input and inward or outward input, and, in FIG. 10(d), a new character is input by successively inputting directional pressing input, inward input and outward input.

The combinational character input enables a larger number of characters to be input, compared to the directional pressing input, the inward input and the outward input.

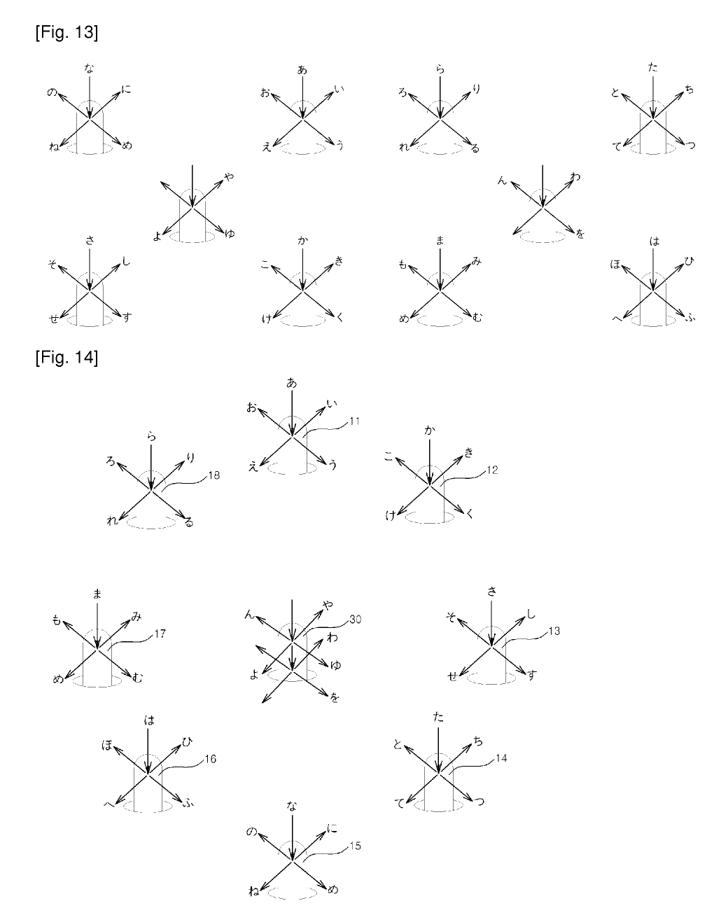

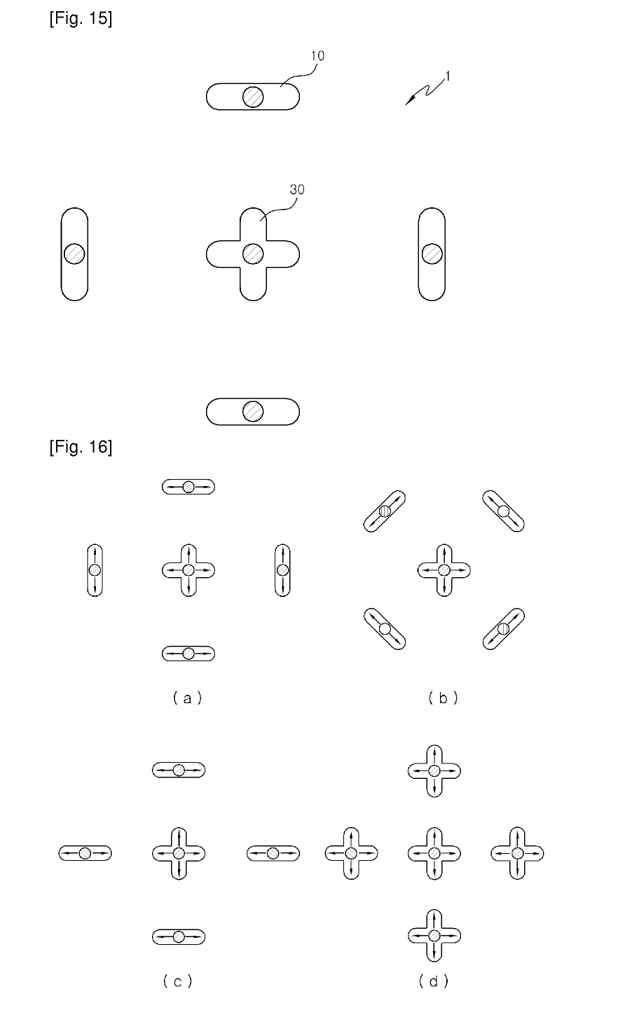

A method of inputting characters through a character input device in the present embodiment will be described with reference to FIGS. 11 to 14. Here, FIGS. 11 and 12 are intended to illustrate a method of inputting Korean characters, and FIGS. 13 and 14 are intended to illustrate a method of inputting Japanese characters.

The method of inputting Korean characters is described first. As shown in FIG. 11, each of the input keys 10 of the character input device enables radial four-direction input (hereinafter referred to as ‘1st stage directional movement input’), two-stage pressing input (hereinafter referred to as ‘1st stage directional pressing input’ and ‘2nd stage directional pressing input’) and radial four-direction input in a pressed state (hereinafter referred to as ‘2nd stage directional movement input’). Accordingly, a total of 10 characters can be input through a single input key 10.

As shown in FIG. 11, at each of four radially arranged input keys 10, a Korean consonant is input through 1st directional movement input, and a Korean vowel is input through 2nd directional movement input. Furthermore, a consonant and a vowel, arranged on each input key 10, are preferably a consonant and vowel of the same derivation in order to facilitate the memorization of the locations of the characters.

Furthermore, [symbol] and [symbol] are assigned to the central input key 30, placed at the center, and function commands, such as Space, Delete, Confirm and Menu, may be arranged for inputs to which Korean consonants or vowels are not assigned in FIG. 11.

Meanwhile, the Korean consonants and vowels shown in FIG. 11 may be assigned to two sets of input keys, as shown in FIG. 12. In greater detail, Korean consonants are arranged on left input keys, and Korean vowels are arranged on right input keys. In this case, function commands, Space, Delete, Confirm and Menu, may be arranged for inputs to which consonants or vowels are not assigned.

Next, the method of inputting Japanese Hiragana and Katakana will be described. As shown in FIGS. 13 and 14, the input of Japanese characters can be implemented using two sets of four-direction input keys or a set of eight-direction input keys.

That is, as shown in FIG. 13, the basic eight characters ( [symbol] [symbol] [symbol] and [symbol] ) of Hiragana are arranged for respective directional pressing inputs of pressing respective keys of two sets of 4-direction input keys 10, and the characters derived from the character of each input key 10 (for example, when a basic character is [symbol] the characters derived from the basic character are [symbol] and [symbol] ) are arranged for respective directional movement inputs. Furthermore, the remaining characters ( [symbol] ), other than basic eight characters, and function commands, such as Space, Delete, Confirm and Menu, are arranged on the central input key 30.

Here, switching from Hiragana to Katakana, shown in FIG. 13, may be performed using one of the function commands.

Furthermore, Japanese Hiragana and Katakana may be implemented using a set of 8-direction input keys, as shown in FIG. 14. That is, the eight basic characters and the characters derived from each basic character are arranged on the respective 8-direction input keys for respective directional pressing inputs and respective directional movement inputs. Furthermore, characters, other than the eight basic characters, and function commands, such as Space, Delete, Confirm and Menu, are arranged on the central input key 30. Here, it is preferred that two-stage directional pressing input and two-stage directional movement input be arranged for the central input key 30 in order to enable the above inputs.

Furthermore, in order to represent voiced consonants, P-sounds and double consonants in Hiragana and Katakana, a corresponding character is transformed into a voiced consonant, a P-sound or a double consonant and is then input by performing directional movement input while performing directional pressing input on a corresponding input key 10.

The method of inputting voiced consonants, P-sounds and double consonants is not limited to the above-described method, but voiced consonants, P-sounds and double consonants may be input based on the number of presses of each input key 10. For example, voiced consonants may be input by performing directional movement input after performing directional pressing input on respective input keys 10 once, and P-sounds may be input by performing directional movement input after performing directional pressing input on respective input keys 10 twice.

It is apparent that the above arrangement of characters may also apply to Chinese characters or the English alphabet. In particular, in the case of Chinese characters, basic characters (or radicals) (for example, [symbol] and [symbol] ) may be arranged for respective directional pressing inputs of input keys, and the Chinese characters or radicals derived from the basic radicals may be input through the respective directional movement inputs of the input keys. For example, when the basic character [symbol] is arranged for the directional pressing input of a specific input key, the derived character [symbol] or the derived radial [symbol] may be input through the directional movement input of the input key. When the basic character [symbol] arranged, the derived Chinese characters or radicals [symbol] and [symbol] may be input.

Furthermore, although FIGS. 11 to 14 show an example of implementation using stick-type input keys, implementation may be performed using sliding button-type input keys shown in FIG. 4, and implementation may be performed using a touch screen, a touch pad or a touch keypad. Furthermore, the number of directions for each input key is not limited to 4 directions or 8 directions, but may be 5 directions, 6 directions, or 7 directions.

Next, a third embodiment of the character input device according to the present invention will be described.

FIG. 15 is a plan view showing a character input device according to the present embodiment, and FIG. 16 is a diagram showing the construction of a method of inputting characters through the character input device according to the present embodiment.

As shown in these drawings, in the character input device of the present embodiment, input keys 10 are implemented as 2-direction sliding button-type input keys, and characters assigned to respective input actions are input through directional movement input and directional movement input in pressed states. Furthermore, assigned characters may be input by performing directional pressing input on the input keys 10. Furthermore, a central input key 30 for performing one or more of directional movement input, directional movement input in a pressed state and directional pressing input may be provided.

In this case, the arrangement of the input keys 10 may be implemented as a set of 4-direction input keys or 8-direction input keys, but the arrangement of the input keys 10 is not limited thereto. Furthermore, the input keys 10 of the present embodiment are not limited to sliding button-type input keys, but may be implemented as stick-type input keys. In the present embodiment, they may be implemented on a touch screen, a touch pad or a touch keypad, other than as the input keys 10.

The implementation method in the present embodiment will be described in detail below.

FIGS. 16(a) to 16(d) are configuration diagrams showing the operation of the input key 10 in the character input device of FIG. 12. As shown in FIG. 16(a), the input keys 10 of the present embodiment are arranged in the circumferential direction on the upper, lower, right and left sides. Each of the input keys 10 enables 1st directional movement input, 2nd directional movement input (in a direction opposite the 1st direction), 1st directional movement input in the state in which the input key 10 is pressed, and 2nd directional movement input in the state in which the input key 10 is pressed, in the tangential direction (a total of four types of directional movement input for each input key 10).

Alternatively, as shown in FIG. 16(b), input keys 10 are arranged diagonally (for example, 45 degrees) around the center. Each of the input keys 10 enables 1st directional movement input, 2nd directional movement input (in a direction opposite the 1st direction), 1st directional movement input in the state in which the input key 10 is pressed, and 2nd directional movement input in the state in which the input key 10 is pressed (a total of four types of directional movement input for each input key 10).

Alternatively, as shown in FIG. 16(c), input keys 10 are arranged in a circumferential direction on the upper, lower, right and left sides. Each of the input keys 10 enables 1st directional movement input, 2nd directional movement input (in a direction opposite the 1st direction), 1st directional movement input in the state in which the input key 10 is pressed, and 2nd directional movement input in the state in which the input key 10 is pressed, in the lateral direction (a total of four types of directional movement input for each input key 10).

Furthermore, as shown in FIG. 16(d), input keys 10 are arranged in a circumferential direction on the upper, lower, right and left sides. Each of the input keys 10 enables 1st directional movement input, 2nd directional movement input (in a direction opposite the 1st direction), 3rd directional movement input, 4th directional movement input (in a direction perpendicular to the 1st and 2nd directions), and 1st, 2nd, 3rd and 4th directional movement input in the state in which the input key 10 is pressed (a total of four types of directional movement input for each input key 10). Here, each input key 10 may be implemented to enable two-stage directional pressing input.

Accordingly, the number of characters that can be input using each input key 10 is four in the cases of FIGS. 16(a) to 16(c) and is eight in the case of FIG. 16(d). Here, each input key 10 enables directional pressing input. If two-stage directional pressing input can be performed, the number of characters that can be performed using each input key 10 is doubled.

Meanwhile, central input keys 30 can input characters through two-stage directional pressing input, 1st directional movement input, 2nd directional movement input (in a direction opposite the first direction), 3rd directional movement input and 4th directional movement input (in a direction perpendicular to the first and second directions) in vertical and lateral directions, and 1st, 2nd, 3rd and 4th directional movement input in the state in which the central input keys 30 are pressed. Accordingly, when the central input keys 30 are taken into account, a number of characters corresponding to 34 types of input (16 types of directional movement input and 8 types of directional pressing input through the four input keys 10, and 8 types of directional movement input and 2 types of directional pressing input through the central input key 30) can be input in the cases of FIGS. 16(a) to 16(c), and characters corresponding to 50 types of input (32 types of directional movement input and 8 types of directional pressing input through the four input keys 10, and 8 types of directional movement input and 2 types of directional pressing input through the central input key 30) can be input in the case of FIG. 16(d).

Although, in the present embodiment, the input of characters is illustrated as being performed using the input keys 10, it may be performed on a touch screen or a touch pad in a touch fashion. Furthermore, 4 types of directional movement input may be basically provided for each of the input keys 10 and the central input key 30, and directional pressing input may be subordinately provided for the input keys 10 and the central input key 30.

Next, a fourth embodiment of the character input device according to the present invention will be described.

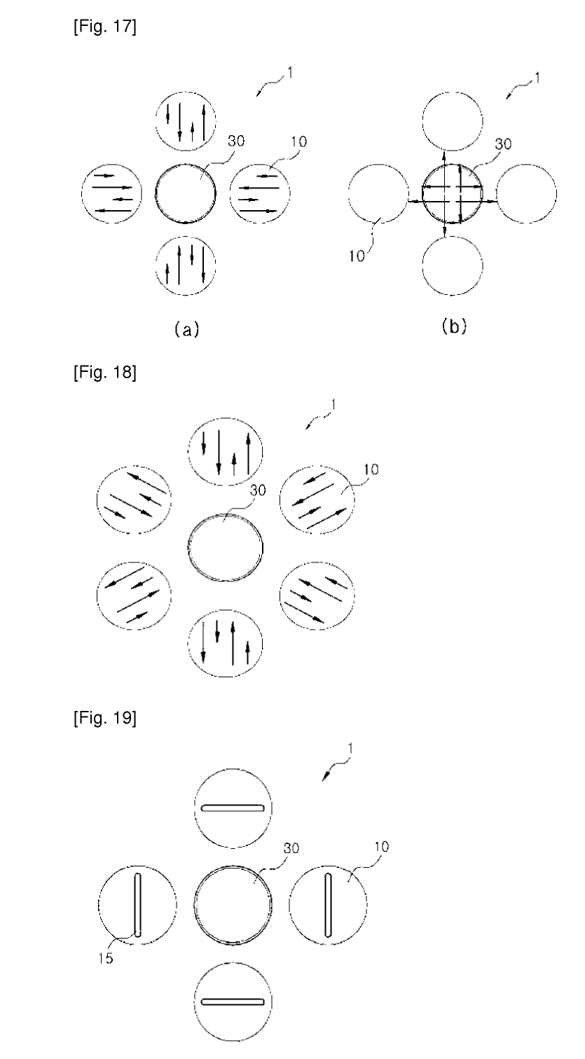

FIGS. 17 to 20 are diagrams showing a fourth embodiment of the character input device according to the present invention.

The input key 10 and central input key 30 of the present embodiment enable the input of characters through directional movement input or directional pressing input, and the directional movement input and the directional pressing input each have two distinct signals.

First, the directional movement input of the input keys 10 and the central input key 30 exerts horizontal force (of course, a small amount of vertical force is exerted for detection). The directional movement input may be divided into a signal related to a short moving distance and a signal related to a long moving distance, or may have two signals that are distinguished from each other based on the intensity of horizontal pressing. When the distance or the intensity of pressing is used, a specific distance or pressure becomes a reference, and the directions of input and the difference in distance or the intensity of pressing will be indicated using arrows in the drawings for the sake of convenience. Furthermore, the directional movement input of the input keys 10 may be divided into inward input in a direction toward the central input key 30 and outward input in a direction away from the central input key 30, and specific pieces of data corresponding to respective characters arranged at respective locations are input based on inward and outward directions.

The above-described character input device may be implemented as an input key-type input device, a touch screen-type input device or a disk-type input device. It is apparent that the types of input device may be implemented in various forms as embodiments for illustrating the character input device of the present invention.

FIGS. 17 to 20 are diagrams showing input key-type character input devices. FIG. 17 shows an embodiment in which a central input key 30 is disposed at the center and 4-direction input keys 10 are provided around the central input key 30 in the circumferential direction. FIG. 17(a) indicates that each of the input keys 10 of the input unit 1 enables the generation of 4 types of signals depending on the direction of a signal and the length of input, and FIG. 17(b) indicates that two types of signal can be generated in each of 4 directions through the input of the central input key 30.

The 4 types of signals of the input key 10 are a first inward signal, a first outward signal, a second inward signal and a second outward signal. This case is characterized in that respective pieces of data, arranged at relevant locations, are input for respective signals (the first and second signals refer to two types of signals that are distinguished between depending on the distance or the intensity of pressing of directional movement input).

The arranged characters may include at least four columns. The arranged characters may include data that can be processed, such as symbols and numbers as well as Korean and English characters, without limitation. It is preferred that the data input through the directional movement input of the input keys 10 be consonants.

In this case, although the central input key 30 may be activated at the same time that each of the input keys 10 is activated it is preferred that the (pressing and movement) detection units 61 and 65 ignore the detection of the activation of the central input key 30 when it is performed within a predetermined time after the activation of the input key 10, but that only the signal of the input key 10 be processed, thereby preventing the erroneous activation of the central input key 30, which is located adjacent thereto.

Furthermore, the input keys 10 may be used to input data, such as characters, numbers or symbols, or perform functions, such as Mode Switch, Cancel, Enter or Space, via four types of radial direction (four directions perpendicular to each other) signals, except for the inward and outward signals.

When it is desired to input a larger number of pieces of data, including characters arranged in four columns, data in two columns can be input using the central input key 30's own signals. In greater detail, this corresponds to the case in which the signals of the central input key 30 include first and second signals. A total of eight pieces of data are arranged, and data corresponding to characters arranged at relevant locations can be input. It is preferred that the data input through the directional movement input of the central input key 30 be vowels.

When four input keys 10 are provided in the circumferential direction around the central input key 30, four pieces of data may be arranged in each of 6 columns on each of the input keys 10, and thus a total of 24 pieces of data can be input. Since users can accurately recognize 4 radial directions, it is preferred that 4 input keys 10 be provided around the central input key 30, and the number of input keys 10 and the number of recognizable directions may vary depending on the type of data and need.

FIG. 18 shows an example in which a central input key 30 and input keys 10 are provided as separate key-type input keys, as in FIG. 17, and 6-direction input keys 10 are provided in the circumferential direction around the central input key 30, which is disposed at the center.

Since the amount of data that can be input increases as the number of input keys 10 that are arranged in a circumferential direction around the central input key 30 increases, as shown in FIG. 18, the present embodiment is suitable for the case in which various types of data are desired to be input without mode switching, in which case the input keys 10 may be configured in various forms within a range in which interference does not occur.

Furthermore, the character input device of the present invention is characterized in that protrusions 15, capable of enabling the clear difference in the length of input to be detected, may be further provided on the input keys 10, as shown in FIG. 19. In this case, it is preferred that the input keys 10 be implemented as a touch screen or a touch pad, rather than as stick-type keys.

The protrusions 15 should be formed to have a height such that a user does not suffer discomfort at the time of performing touch input. It is preferred that they be formed to indicate regions in which input is possible to the user.

Although the protrusions 15 have been illustrated in the form of long bars in FIG. 19, they may be configured in various forms, such as semi-circular, dotted line-shaped or circular protrusions.

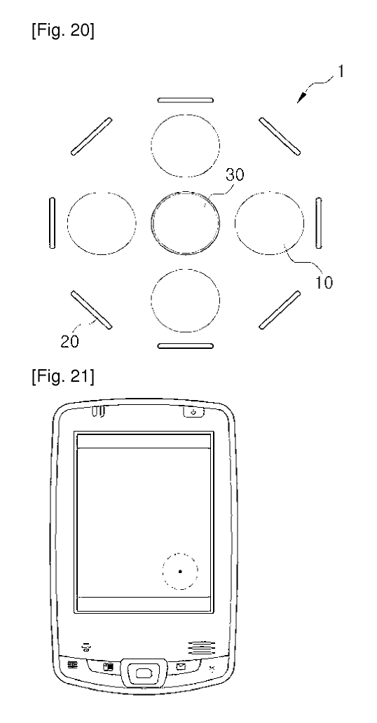

FIG. 20 shows an example in which outside input keys 20 are arranged in a circumferential direction around the input keys 10. Although FIG. 20 shows a configuration in which six detection lines are formed around the input key 10, it is possible to form outside input keys 20 in various numbers depending on the type of data. The outside input keys 20 may be configured in the form of button-type keys, such as the central input keys 30 and the input keys 10 shown in FIGS. 17 to 19, and it is apparent that they may be fabricated in various forms.

In the case in which the outside input keys 20 are provided, data corresponding to a character arranged at a relevant location can be input when an outside input key 20 is detected, or an input key 10 and an outside input key 20 are detected within a predetermined time.

Furthermore, as shown in FIGS. 17 to 20, when the input unit 1 of the present invention is configured in the form of input keys, the respective keys may be implemented as device pointers.

Since the stick pointers enable lateral movement or lateral and vertical movement, as well as vertical pressing input, they provide the sensation of motion to a user, thereby enabling more accurate input.

Furthermore, it is apparent that a sliding-type input unit 1, similar to the illustrated stick pointers, may be used besides the stick pointers.

FIG. 21 shows an application example of the character input device according to the fourth embodiment, which can be implemented on a touch screen, as in a PDA. In the case in which the character input device of the present invention is implemented on a touch screen, a central input key 30 and input keys 10 are characterized in that the central input key 30 is implemented as a small dot, representative of a reference on the screen, and the input keys 10 are arranged within a specific region in a radial direction around the central input key 30.

In the case in which the central input key 30 is implemented in a small spot form, the term ‘spot form’ is a term that includes a circular form and a polygonal form, and the central input key 30 in the spot form is implemented to function as a reference for enabling a user to detect it.

In the touch screen-type input unit, the central input key 30 is implemented as a small spot that can be recognized by a user, and the central input key 30 can be set to a transparent state. The touch screen-type input unit has an advantage in that a screen is viewed at the same time that input is performed, and thus a separate space on the screen is not required for input, thereby more efficiently utilizing the screen.

Furthermore, the input unit 1 may be moved across the screen. It is preferred that the input unit 1 be moved by inputting a specific signal and then dragging the input unit 1 to a desired location. Here, the specific signal may be generated by clicking the central input key 30 or an input key 10 twice within a predetermined time. It is preferable to allow the input unit 1 to be moved after the input of the specific signal, thereby preventing the input of general data from being disturbed.

Furthermore, the input device has a waiting region on one side of the screen, to which the central input key 30 can be moved. The waiting region is characterized in that the region of the input keys 10 disappears when the central input key 30 is moved to the waiting region and the region of the input keys 10 appears when the central input key 30 is moved out of the waiting region. That is, it is preferred that setting be performed such that, when the input unit 1 is not necessary, a waiting region exist on a side of a screen and the region of the input keys 10 disappear or appear, as in a typical Windows environment.

Furthermore, it is preferred that the region of the input keys 10 disappear through the waiting region. It is possible to perform setting such that the region of the input keys can appear through an action of touching the waiting region twice or rubbing the waiting region, as well as an action of moving the central input key 30.

In the case in which the character input device of the present invention is implemented on a touch screen, it is preferred that the first signal and the second signal be discriminated from each other based on the length of input. The detection unit can discriminate between the first signal and the second signal through the analysis of the locations of first and final signals.

Existing PDAs have disadvantages in that a separate screen for touch input is formed and a button region corresponding to the input keys 10 is provided on the screen, so that erroneous input occurs because an adjacent button may be touched along with each button when the button is touched, and the use thereof is inconvenient because a region in which buttons are formed covers another window. However, as described above, the present invention has an advantage in that input can be performed without covering a screen by using a minimal region and setting the region of each input key 10 to a transparent state.

Furthermore, the character input device of the present invention has an advantage in that it can be applied to various information devices, such as various devices using touch screens as well as a PDA, as in the above-described method.

Next, a fifth embodiment of the character input device of the present invention will be described below.

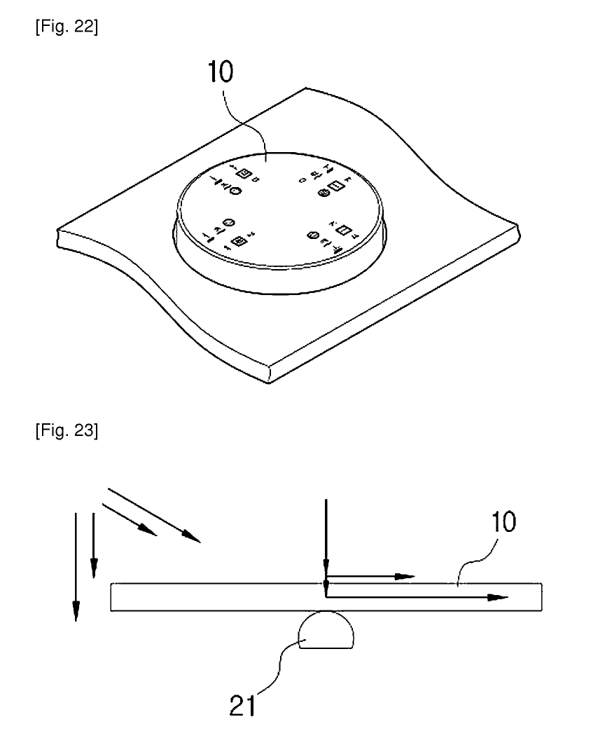

The character input device of the present embodiment may be configured in the form of a disk-type input unit 1, an example of which is illustrated in FIG. 22.

The disk-type character input device of the present embodiment is characterized in that it provides a character input device, including an input unit 1 for inputting data in response to one or more signals, a detection unit (not shown) for detecting signals from the input unit, and a control unit (not shown) for detecting one or more effective signals from among the signals detected by the detection unit and creating data, wherein the input unit 1 is configured in the form of a plate in which a central input key 30, which is a reference, and input keys 10, which are arranged in radial directions around the central input key 30 and on which characters arranged in a plurality of columns are arranged, are integrated, and wherein the central input key 30 or the input key 10 enables directional movement input, and inputs specific data corresponding to a character at a relevant location through pressing input. Furthermore, the disk enables lateral movement in a radial direction, and the directional movement input and pressing input of the central input key 30 or the input key 10 have two distinct signals.

The directional movement input of the input key 10 may be divided into inward input in a direction toward the central input key 30 and outward input in a direction away from the central input key 30. Accordingly, specific data corresponding to a character arranged at a relevant location is input depending on an inward or outward direction. In this case, the detection unit determines that a signal in question is an outward signal only if a signal from an input key 10 is detected, and determines that a signal in question is an inward signal if a signal from an input key 10 is detected and a signal from the central input key 30 is detected within a predetermined time.

The disk-type character input device may further include an elastic element 80 at the center so that the disk can be moved. The character input device of the present invention may include one of various means as long as the means is configured to support the disk, enables each of the central input key 30 and the input keys 10 to have first and second distinct signals, and enables the disk to be moved laterally, besides the elastic element 80.

When a signal from an input key 10 based on the movement of the disk is detected along with a first signal from the central input key 30 and when a signal from an input key 10 based on the movement of the disk is detected along with a second signal from the central input key 30, data corresponding to a character arranged at each relevant location can be input.

As shown in FIG. 23, when the input unit 1 is configured in the form of a disk in which the central input key 30 and the input keys 10 are integrated together, it is preferred that the first signal and the second signal be a 1st pressing input and a 2nd pressing input, which are distinguished from each other based on the type of pressing. In greater detail, with reference to FIG. 22, data at relevant locations can be input through a 1st pressing input and a 2nd pressing input, in each of which only a signal from an input key 10 is detected, and a 1st pressing input and a 2nd pressing input, to each of which a signal, which is detected within a predetermined time after a signal from an input key 10 is detected, corresponds, that is, via four types of signals. Furthermore, data corresponding to characters arranged at respective locations can be also input in two cases: the case in which the movement of the disk is performed along with the 1st pressing input of the central input key 30 and the case in which the movement of the disk is performed along with the 2nd pressing input of the central input key 30.

When the 1st pressing input and the 2nd pressing input are employed, the detection unit may use a push switch for performing switching as the central input key 30 is moved by being pressed by a user or a pressure sensor for detecting pressure applied by a user, and a return member for returning the central input key 30 to an original location at which pressing input was performed may be further included.

The 1st-stage pressing input may be detected by being softly pushed down using weak force, and the 2nd-stage input may be detected when the central input key 30 is pressed using strong force. In this case, the detection unit may be further provided with a metal dome in order to realize the difference between the 1st pressing input and the 2nd pressing input. The case in which the metal dome is provided has advantages in that the metal dome is switched at the time of 2nd pressing input, and thus a user can feel the sensation of a click, thereby enabling a user to discriminate between the two types of input and reducing erroneous manipulation by a user. At the time of 2nd pressing input, input is detected after 1st pressing input has been performed. Accordingly, when 1st pressing input and 2nd pressing input are performed within a predetermined time, the control unit ignores a signal based on the 1st pressing input and processes only a signal based on the 2nd pressing input, so that the 1st pressing input and the 2nd pressing input can be distinguished from each other, and thus respective pieces of data can be input.

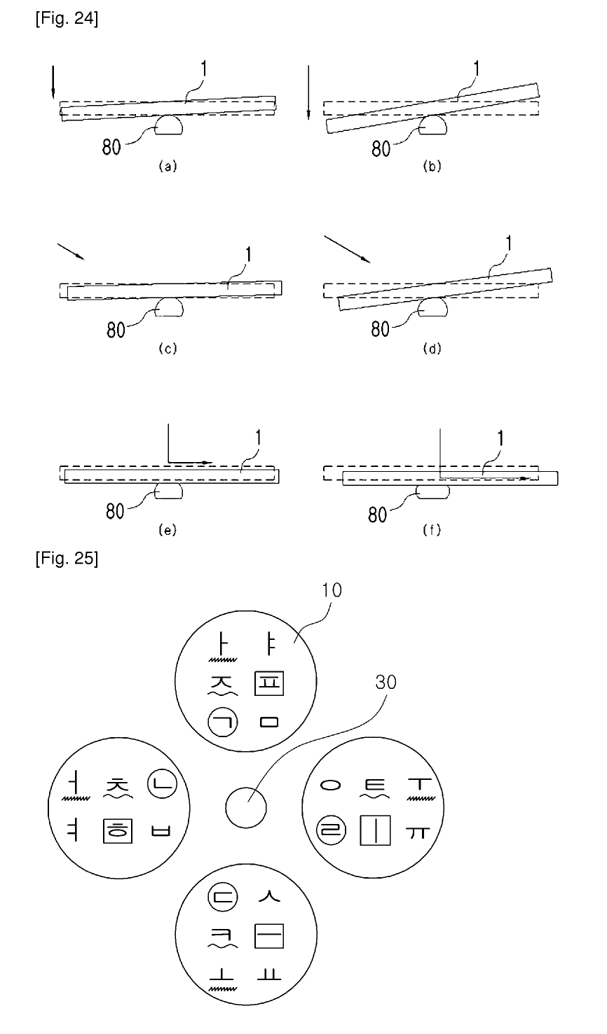

FIG. 24 is a conceptual diagram illustrating the operation of the character input device shown in FIG. 22. FIG. 24(a) and FIG. 24(b) shows the case in which a signal from the input key 10 is generated through 1st pressing input and is determined to be an outward signal and the case in which a signal from the input key 10 is generated through 2nd pressing input and is determined to be an outward signal, respectively. FIG. 24(c) and FIG. 24(d) show the cases in which a signal from an input key 10 and a signal in a direction toward the central input key 30 are detected. In detail, FIG. 24(c) and FIG. 24(d) show the case in which a signal in question is determined to be an inward signal based on 1st pressing input in a direction toward the central input key 30 and the case in which a signal in question is determined to be an inward signal based on 2nd pressing input in a direction toward the central input key 30, respectively.

Furthermore, FIG. 24(e) and FIG. 24(f) show the case in which the 1st pressing input of the central input key 30 is performed and the disk is moved in a direction toward the input key 10 and the case in which the 2nd pressing input of the central input key 30 is performed and the disk is moved in a direction toward the input key 10, respectively.

As shown in FIGS. 24(a) to 24(f), the present embodiment is characterized in that data corresponding to characters arranged at relevant locations is input in various forms. The data input through the input unit 1 may include all characters and symbols. It is preferred that signals input through the input key 10 be four types of signals, including the first inward signal, the first outward signal, the second inward signal and the second outward signal, or that, in the method shown in FIGS. 24(a) to 24(d), the data input via the signals be consonants. It is preferred that signals input through the input keys within a predetermined time after signals from the central input key 30 have been detected be two types of signals, including a first signal and a second signal, or that, in the method shown in FIGS. 24(e) and 24(f), data input via the signals be vowels.

In the case of foreign languages, vowels are considered to be characters that correspond to Korean vowels from the viewpoint of pronunciation or belong to a relatively small alphabet group when a relevant foreign language alphabet is divided into two groups based on linguistic classification criteria.

Since the number of consonants is greater than that of vowels and the frequency of use of consonants is higher than that of vowels, consonants are input using the former method, which has a shorter path, while vowels are input using the latter method, thereby enabling faster input.

Although FIG. 24 shows the case in which the first signal is based on 1st pressing input and the second signal is based on 2nd pressing input, signals may be set as long as the signals are distinct signals that can be easily distinguished by a use and can be input through the appropriate combinations of the central input key 30 and the input keys 10.

FIG. 25 is a conceptual diagram showing an example of the arrangement of the Korean characters of a character input device according to the present embodiment. Although FIG. 25 shows the case in which 4-direction input keys 10 are arranged in a circumferential direction near the central input key 30 and Korean characters are arranged on each of the input keys 10 in six columns, various types of arrangements can be provided based on data used by users.

In greater detail, the drawing shows the case in which input keys 10 are used to input “ [symbol] and [symbol] ” when signals input through the input keys 10 are first inward signals, input keys 10 are used to input “ [symbol] and [symbol] ” when signals input through the input keys 10 are second inward signals, input keys 10 are used to input “ [symbol] and [symbol] ” when signals input through the input keys 10 are first outward signals, and input keys 10 are used to input “ [symbol] and [symbol] ” when signals input through the input keys 10 are second outward signals.

Furthermore, the drawing shows the case in which “ [symbol] and [symbol] ” are input when signals based on the directional movement input of the central input key 30 are first signals, and “ [symbol] and [symbol] ” are input when signals based on the directional movement input of the central input key 30 are second signals.

Of course, in the character input device of the present invention, arranged characters associated with the input signals may be configured in various manners. Furthermore, although vowels and consonants may be input when signals input through the input keys 10 correspond to second outward signals, the two sets of vowels may be separately input via two distinct signals from the center input key.

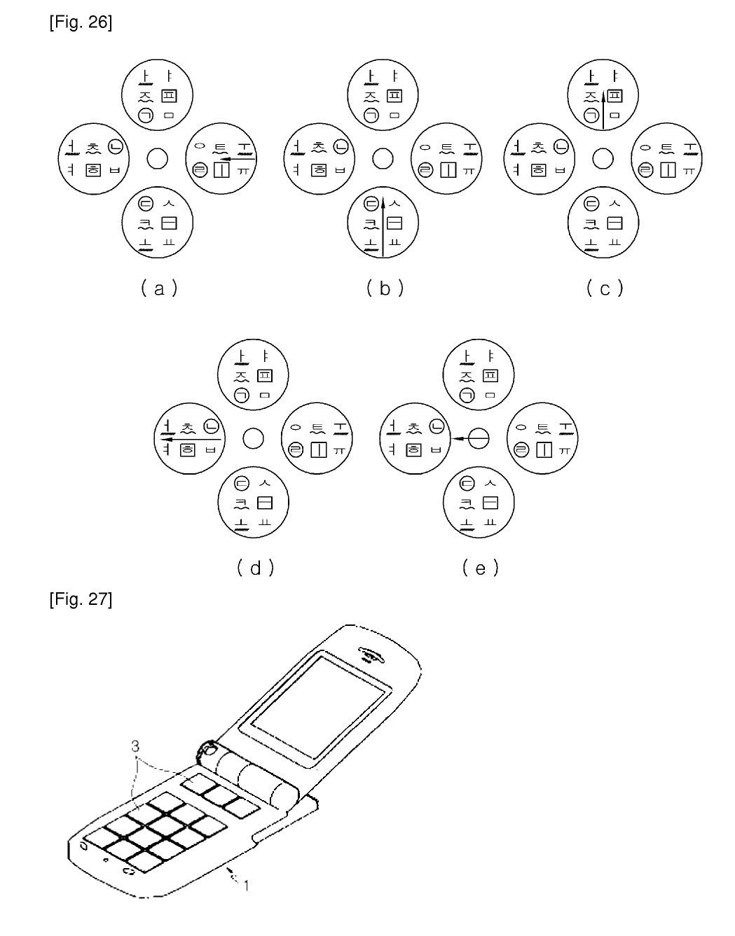

FIG. 26(a) to 26(e) are conceptual views showing examples of the input of the character input device according to the present embodiment. These drawings illustrate the input of the term “ [symbol] ” based on the embodiment shown in FIG. 25.

The input of the syllable “ [symbol] ” is performed in such a way that a first outward signal is input through the input key 10, on which the character “ [symbol] ” is arranged and which is located to the right side of the central input key 30, in order to input the character “ [symbol] ”, as indicated by the arrow of FIG. 26(a), a second outward signal is input through the input key 10, on which the character “ [symbol] ” is arranged and which is located to the lower side of the central input key 30, in order to input the character “ [symbol] ”, as indicated by the arrow of FIG. 26(b), and a first inward signal is input through the input key 10, on which the character “ [symbol] ” is arranged and which is located to the upper side of the central input key 30, in order to input the character “ [symbol] ”, as indicated by the arrow of FIG. 26(c).

Furthermore, the input of the syllable “ [symbol] ” is performed in such a way that the character “ [symbol] ” is input by inputting a second outward signal through the input key 10, on which the character “ [symbol] ” is arranged and which is located to the left side of the central input key 30, as indicated by the arrow in FIG. 26(d), and the central input key 30 inputs a second signal toward the input key 10, on which the character “ [symbol] ” is arranged and which is located to the left side of the central input key 30, within a predetermined time, as indicated by the arrow in FIG. 26(e).

Furthermore, another embodiment of the character input device of the present invention will be described below. As shown in FIG. 17, a central input key 30, which is a reference, and input keys 10, which are provided in four directions around the central input key 30, are provided, the input keys 10 can generate a total of eight signals with each inward signal in a direction toward the central input key 30 set to two distinct signals, and the input keys 10 can generate a total of eight signals with each outward signal in a direction away from the central input key 30 set to distinct signals. In this case, the input keys 10 can independently generate a total of eight signals because they can make two signals distinct from each other based on a method such as touch/pressing or 1st-stage pressing/2nd-stage pressing, thus being able to input data using a total of 24 signals.

Two distinct signals of the inward input or outward input of the input key 10 may be discriminated from each other based on moving distance, pressure, or displacement, or may be discriminated from each other based on movement or simultaneous signals of movement and pressing.

As described above, the character input device of the present invention has a reduced number of input keys, so that the area in which the input unit 1 is provided is decreased and at the same time, various pieces of data can be input through the combinations of input methods, erroneous manipulation can be prevented by eliminating repeated manipulation, and the convenience of input of data can be increased through a simple method of use.

The present invention is not limited to the above-described embodiments, but may be applied to various fields and may be modified and practiced in various ways without departing from the gist of the present invention claimed in the attached claims.

1. A character input device including a plurality of directional input keys, comprising: input means comprising four input keys that are arranged in four radial directions around a center so that distances between adjacent input keys are uniform; wherein the respective input keys are provided such that they can be moved toward a plurality of direction indication locations arranged in radial directions around a reference location, and can perform directional movement input for inputting characters assigned to the respective direction indication locations.

2. The character input device as set forth in claim 1, wherein the directional movement input is provided to enable two or more-stage input, that is, multistage input, based on a moving distance of each of the input keys.

3. The character input device as set forth in claim 1, wherein each of the input keys is provided to enable directional pressing input in which the entire input key is moved in a vertical direction.

4. The character input device as set forth in claim 3, wherein the directional pressing input is provided to enable two or more-stage input, that is, multi-stage input, based on any one of differences in pressing distance and pressing pressure of the input key.

5. The character input device as set forth in claim 3, wherein consonant characters are input through the directional movement input and vowel characters are input through the directional pressing input.

6. The character input device as set forth in claim 1, further comprising a central input key that is provided at the center and enables one or more of the directional movement input and the directional pressing input.

7. The character input device as set forth in claim 6, wherein: the central input key is provided to enable two or more-stage input, that is, multistage input; and consonant characters are input through the directional movement input of the four input keys and vowel characters are input through the directional movement input of the central input key.

8. The character input device as set forth in claim 1, wherein the input keys are five or more in number.

9. The character input device as set forth in claim 1, wherein:
the input keys are arranged at regular intervals in a circle having a predetermined radius around the center; and vowel characters are input through directional movement input of the respective input keys in radial directions of the circle, and consonant characters are input through direction movement input in directions perpendicular to the radial directions.

10. The character input device as set forth in claim 1, wherein: the input keys are arranged at regular intervals in a circle having a predetermined radius around the center; and consonant characters are input through directional movement input of the respective input keys in radial directions of the circle, and vowel characters are input through direction movement input in directions perpendicular to the radial directions.

11. The character input device as set forth in claim 1, wherein consonant characters are input through forward/backward directional movement input of the respective input keys in radial directions of the circle, and vowel characters are input through forward/backward direction movement input in directions perpendicular to the radial directions.

12. The character input device as set forth in claim 1, wherein vowel characters are input through forward/backward directional movement input of the respective input keys in radial directions of the circle, and consonant characters are input through forward/backward direction movement input in directions perpendicular to the radial directions.

13. The character input device as set forth in claim 1, wherein the input keys are stick-type input keys that can be titled from the reference location toward the respective direction indication locations.

14. The character input device as set forth in claim 1, wherein the input keys are sliding button-type input keys that can be laterally moved from the reference location toward the respective direction indication locations.

15. The character input device as set forth in claim 13, further comprising return units for returning the input keys to the reference location after performing the directional movement input.

16. The character input device as set forth in claim 6, wherein the character input device, comprising the plurality of input key or the central input key, comprises two sets of character input devices on right and left sides.

17. The character input device as set forth in claim 6, wherein consonant characters are input through any one of the directional movement input, the directional pressing input and the central input.

18. The character input device as set forth in claim 3, wherein the directional movement input is provided to enable two-stage input in the radial directions and one-stage input in directions perpendicular to the radial directions, the directional pressing input is provided to enable two-stage input, consonant characters can be input through the directional movement input, and vowel characters can be input through the directional pressing input.

19. The character input device as set forth in claim 6, wherein the directional movement input is provided to enable one-stage input in directions perpendicular to the radial directions, the directional pressing input is provided to enable two-stage input, the central input is provided to enable two-stage input in the radial directions, vowel characters are input through the directional pressing input, and consonant characters are input through the directional movement input and the central input.

20. The character input device as set forth in claim 1, wherein the directional movement input enables two or more-stage input, that is, multi-stage input, in each of a state in which each of the input keys is pressed and a state in which the input key is not pressed based on a distance of the input key.

21. The character input device as set forth in claim 20, wherein each of the input keys is provided to enable directional pressing input in which the entire input key is moved in a vertical direction.

22. The character input device as set forth in claim 21, wherein the directional pressing input is provided to enable two or more-stage input, that is, multi-stage input, based on any one of differences in pressing distance and pressing pressure of the input key.

23. The character input device as set forth in claim 20, further comprising a central input key that is provided at the center and enables one or more of the directional movement input and the directional pressing input in which the entire input key is moved in a vertical direction.

24. The character input device as set forth in claim 1, wherein characters arranged on each of the input keys are characters that are similar to each other in shape or have a same origin.

25. A character input device comprising input means configured to have a plurality of directional input keys and to input data in response to one or more signals, a detection unit for detecting one or more signals from the input means, and a control unit for detecting one or more effective signals from among the signals detected by the detection unit and creating data, wherein: the input means is configured to include a first input unit, which is a reference, and second input units, which are formed in radial directions from the first input unit and on which characters arranged in a plurality of columns are arranged; and the first input unit or each of the second input units enables directional movement input and pressing input (vertical pressing input), and inputs specific data corresponding to a character arranged at a relevant location through the directional movement input or the pressing input.

26. The character input device as set forth in claim 25, wherein the directional movement input of the first input unit or the second input units is performed via two distinct signals.

27. The character input device as set forth in claim 25, wherein the pressing input of the first input unit or each of the second input units is performed via two distinct signals.

28. The character input device as set forth in claim 26, wherein the directional movement input of the second input units is divided into inward input in a direction toward the first input unit and outward input in a direction away from the first input unit, and specific data corresponding to characters arranged at relevant locations is input based on the inward input and the outward input.

29. The character input device as set forth in claim 28, wherein the data input through the directional movement input of the second input units are consonants.

30. The character input device as set forth in claim 28, wherein the second input units are configured to input data, such as characters, numbers or symbols, or perform functions (inputs), such as Mode Switch, Cancel, Enter or Space, via the four radial signals, except for the inward and outward signals.

31. The character input device as set forth in claim 26, wherein data input through the directional movement input of the first input unit is vowels.

32. The character input device as set forth in claim 27, wherein data, such as a character, a number or a symbol, is input or a functions (input), such as Mode Switch, Cancel, Enter or Space, is input through the pressing input of the first or each of the second input units.

33. The character input device as set forth in claim 26, wherein the directional movement input of each of the second input units is divided into a signal related to a short distance and a signal related to a short distance.

34. The character input device as set forth in claim 25, wherein the first input unit and the second input units are input key-type input units that are formed as separate input keys.

35. The character input device as set forth in claim 34, wherein the input keys are respective device pointers.

36. The character input device as set forth in claim 25, wherein the input means is implemented on any one of a touch screen, a touch pad and a touch keypad.

37. The character input device as set forth in claim 36, wherein the second input units are provided with protrusions in order to easily discriminate between distances related to input of signals.

38. The character input device as set forth in claim 37, wherein the first input unit of the input means is implemented on a screen in a form of a spot for indicating a reference, and the second input units of the input means are formed in a predetermined region in a circumferential direction around the first input unit.

39. The character input device as set forth in claim 38, wherein the input means can be moved across the screen.

40. The character input device as set forth in claim 39, wherein the movement of the input means is performed after the first input unit or one of the second input units is clicked twice within a predetermined time.

41. The character input device as set forth in claim 40, wherein the input device is configured such that a waiting region, to which the first input unit can be moved, is provided on one side of the screen, the region of the second input units disappears when the first input unit is moved to the waiting region, and the region of the second input units appears when the first input unit is moved from the waiting region.

42. The character input device as set forth in claim 37, wherein the second input units are configured such that transparency thereof can be adjusted.

43. A character input device comprising input means configured to have a plurality of directional input keys and to input data in response to one or more signals, a detection unit for detecting one or more signals from the input means, and a control unit for detecting one or more effective signals from among the signals detected by the detection unit, and creating data, wherein:
the input means is configured in a form of a disk in which a first input unit, which is a reference, and second input units, which are formed in radial directions around the first input unit and on which characters arranged in a plurality of columns are arranged, are integrated together; and the first input unit or each of the second input unit enables directional movement input and pressing input (vertical pressing input), and inputs specific data corresponding to a character arranged at a relevant location through the directional movement input or the pressing input.

44. The character input device as set forth in claim 43, wherein the disk can be laterally moved in a circumferential direction.

45. The character input device as set forth in claim 44, wherein the directional movement input of the first input unit or the second input units is performed via two distinct signals.

46. The character input device as set forth in claim 44, wherein the pressing input of the first input unit or each of the second input units is performed via two distinct signals.

47. The character input device as set forth in claim 44, wherein the directional movement input of each of the second input units is divided into inward input in a direction toward the first input unit and outward input in a direction away from the first input unit, and specific data corresponding to characters arranged at relevant locations is input based on the inward input and the outward input.

48. The character input device as set forth in claim 47, wherein the detection unit determines that a signal in question is an outward signal if only a signal from one of the second input units is detected, and determines that a signal in question is an inward signal if a signal from the first input unit is detected within a predetermined time after a signal from one of the second input units is detected.

49. The character input device as set forth in claim 45, wherein data input through the directional movement input of the first input unit is a vowel.

50. The character input device as set forth in claim 25, wherein the second input units are configured to perform a volume adjustment function or a mouse scrolling function via a continuous signal in a circumferential direction.

51. The character input device as set forth in claim 25, wherein the input means further comprises third input units in a circumferential direction around the second input units.

52. The character input device as set forth in claim 14, further comprising return units for returning the input keys to the reference location after performing the directional movement input.

53. The character input device as set forth in claim 43, wherein the second input units are configured to perform a volume adjustment function or a mouse scrolling function via a continuous signal in a circumferential direction.

54. The character input device as set forth in claim 43, wherein the input means further comprises third input units in a circumferential direction around the second input units.
